(19) United States
(12) Patent Application Publication
(10) Pub. No.: US 2007/0252170 A1
(43) Pub. Date: Nov. 1, 2007

(54) Electrostatic discharge protection device for optical drive

(75) Inventors: Sen Lin, Taoyuan (TW); Hsien-Chung Oh, Taoyuan (TW)

Correspondence Address: BACON & THOMAS, PLLC, 625 SLATERS LANE, FOURTH FLOOR, ALEXANDRIA, VA, 22314, US

(73) Assignee: QUANTA STORAGE INC., Taoyuan (TW)

(21) Appl. No.: 11/727,021

(22) Filed: Mar. 23, 2007

(30) Foreign Application Priority Data
Apr. 28, 2006 (TW) 95115667

(51) Int. Cl. H01L 29/74

(52) U.S. Cl. 257/173

(57) ABSTRACT

An electrostatic discharge protection device for an optical drive is a circuit on a printed circuit board, which is disposed between a tray and a panel of the optical drive and attached to a front end surface of the tray. The panel has a button, an indicator hole and an emergency ejecting hole. The electrostatic discharge protection device includes a push switch circuit enabled by the button to make the optical drive eject a disk, a light-emitting diode circuit, and at least one bare wire, which is formed on a grounding bare circuit on the printed circuit board and disposed near the push switch circuit, the light-emitting diode circuit and the emergency ejecting hole. A metallic bottom plate contacting the bare wire covers a backside of the tray, and is connected to a main circuit board through a flexible cable to form a grounding path for discharging electrostatic charges.

This application claims the benefit of Taiwan application Serial No. 95115667, filed Apr. 28, 2006, the subject matter of which is incorporated herein by reference.

### BACKGROUND OF THE INVENTION

1. Field of the Invention

The invention relates in general to an electrostatic discharge protection device, and more particularly to an electrostatic discharge protection device capable of discharging electrostatic charges of an operator and preventing the electrostatic charges from damaging precise elements in an optical drive.

2. Description of the Related Art

An optical drive among home appliance information products needs very precise electronic elements so as to read high density data on an optical disk rotating at a high speed. However, when the optical drive is operating, the precise electronic elements tend to be influenced and damaged by electrostatic charges of the user. So, the electrostatic discharge protection is greatly needed.

Referring to FIG. 1, a conventional optical drive 1 mainly includes a metallic casing 2 and a disk tray 3. The casing 2 has a hollow region allowing the tray 3 to be moved in and out. A motor for rotating an optical disk, an optical pickup for reading and writing data, and associated control electronic elements are disposed on the tray 3. A thin printed circuit board 4, on which an optical drive operating switch 5 is disposed, is disposed at the front end of the tray 3. The front of the tray 3 is adjacent to a panel 6. The panel 6 has a button 7 at a position corresponding to the switch 5. The button 7 may pass through a through hole 8 of the panel 6 to push the switch 5. A metal sheet 9 is attached to a backside of the panel 6 and is formed with a slot 10 surrounding the through hole 8. A rubber sheet 11 is disposed between the metal sheet 9 and the panel 6 in order to enhance the elasticity of the metal sheet 9. Thus, when the tray 3 enters the optical drive 1, the rubber sheet 11 presses against the metal sheet 9 tightly to make the metal sheet 9 and the casing 2 contact each other.

When the user presses the button 7 of the optical drive 1 to eject the disk, the electrostatic charges of the user are discharged to the metal sheet 9 through a finger 12 for pressing the button 7 and through the slit of the through hole 8 between the panel 6 and the button 7. The electrostatic charges are discharged from the metal sheet 9 to the casing 2, and then grounded through a grounding path of the casing 2. Thus, the object of preventing the electrostatic current from flowing through the precise electronic elements on the tray 3 can be achieved so that the electrostatic charge protection can be achieved. However, the conventional optical drive needs an electrostatic discharge device, such as the metal sheet 9 or the rubber sheet 11, so the number of elements is increased, the time for assembling the optical drive is lengthened, and the manufacturing cost is high. In addition, the conventional optical drive only can discharge the electrostatic charges when the tray enters the casing, but cannot discharge the electrostatic charges when the tray is moved out of the casing so that the motor for rotating the disk, the optical pickup and the printed circuit board containing the control electronic elements are directly exposed outside. Thus, the precise electronic elements tend to be damaged, and the quality of the optical drive is thus deteriorated. Thus, the electrostatic discharge protection for the conventional optical drive still has to be improved.

### SUMMARY OF THE INVENTION

The invention is directed to an electrostatic discharge protection device for an optical drive, wherein the electrostatic discharge protection device is formed by an original printed circuit board for an original push switch of the optical drive, and directly discharges electrostatic charges to simplify the structure and reduce the manufacturing cost.

The invention is also directed to an electrostatic discharge protection device for an optical drive, wherein electrostatic charges can be effectively discharged when a tray is moved into or out of a casing so that the function of electrostatic discharge protection of the optical drive can be enhanced.

According to the present invention, an electrostatic discharge protection device for an optical drive is provided. The electrostatic discharge protection device is a circuit of a printed circuit board, disposed between a tray of the optical drive and a panel of the optical drive, and attached to a front end surface of the tray. The panel has a button, an indicator hole and an emergency ejecting hole. The electrostatic discharge protection device includes a push switch circuit enabled by the button to enable the optical drive to eject a disk, a light-emitting diode circuit and at least one bare wire. The bare wire is formed on a grounding bare circuit on the printed circuit board and disposed near the push switch, the light-emitting diode and the emergency ejecting hole. The backside of the tray covers a metallic bottom plate contacting the bare wire, and is connected to a main circuit board through a flexible cable to form a grounding path for discharging electrostatic charges.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view showing an electrostatic discharge protection device for a conventional optical drive.

FIG. 2 is an exploded view showing elements on a backside of the optical drive using the electrostatic discharge protection device of the invention.

FIG. 3 is a schematically cross-sectional side view showing a tray of the invention, which is moved out of a casing.

FIG. 4 is a partially schematically cross-sectional side view showing the optical drive of FIG. 2 taken along the line A-A.

FIG. 5 is a front view showing the electrostatic discharge protection device of the invention.

FIG. 6 is a front view showing an electrostatic discharge protection device according to another embodiment of the invention.

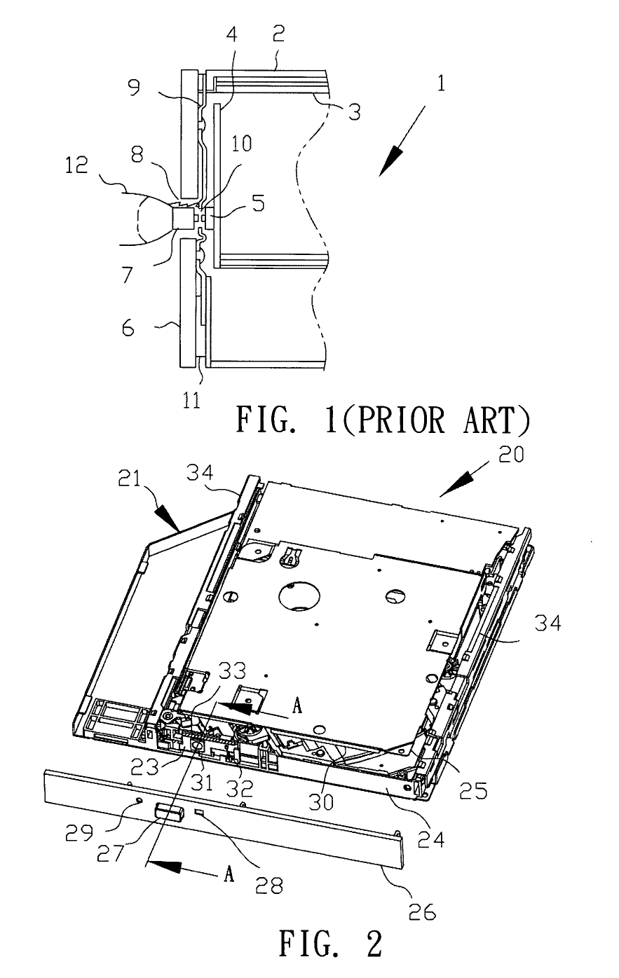

### DETAILED DESCRIPTION OF THE INVENTION

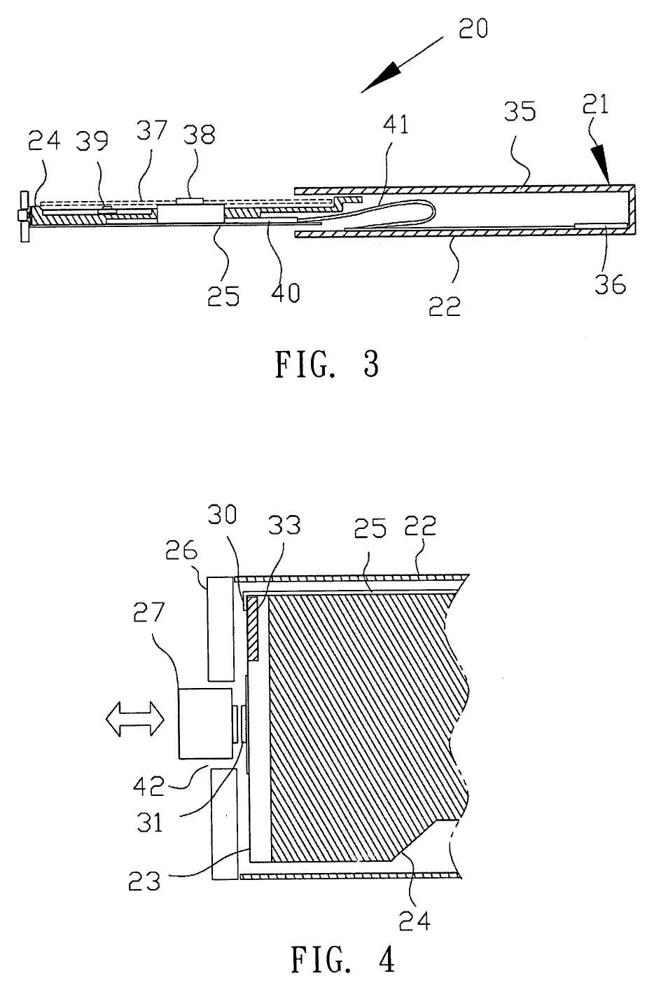

FIG. 2 is an exploded view showing elements on a backside of an optical drive 20 using the electrostatic discharge protection device of the invention, wherein a lower casing 22 (see FIG. 3) of a casing 21 of the optical drive 20 is removed so that the electrostatic discharge protection device 23 of the invention can be clearly illustrated. The optical drive 20 includes the casing 21, the electrostatic discharge protection device 23, a tray 24, a bottom plate 25, a panel 26 and a button 27. The electrostatic discharge protection device 23 attached to the front end surface of the tray 24 discharges electrostatic charges through a grounding path of the bottom plate 25 on the backside of the tray 24 when the user pushes the button 27 on the panel 26 and the electrostatic charges of the user pass through the slits around the button 27.

The front end of the tray 24 is connected to the panel 26, on which the button 27, an indicator hole 28 and an emergency ejecting hole 29 are disposed or formed. The backside of the tray 24 covers the metallic bottom plate 25 for preventing the electromagnetic interference (EMI) and protecting the electronic elements in the tray 24. The front end of the bottom plate 25 is formed with several bent flanges 30. The electrostatic discharge protection device 23 is attached to the front end surface of the tray 24 corresponding to the position of one of the flanges 30. The electrostatic discharge protection device 23 is a circuit of a printed circuit board and includes a push switch 31, a light-emitting diode 32 and a bare wire 33 (depicted by the oblique line). The push switch 31 is disposed at a position corresponding to the button 27. When the user pushes the button 27, the button 27 triggers a disk-ejecting switch circuit of the optical drive. The light-emitting diode 32 is disposed at the position corresponding to the indicator hole 28, and displays the operating condition of the optical drive. The bare wire 33 for grounding the electrostatic charges is formed when the push switch 31 and the printed circuit board of the light-emitting diode 32 are formed in the optical drive without influencing the normal circuit. The bare wire 33 is disposed near the button 27, the indicator hole 28 and the emergency ejecting hole 29 of the panel 26 and is formed with the redundant circuit or formed by adding a portion of the circuit.

In addition, guide rails 34 for supporting the tray 24 to slide into and out of the casing 21 are disposed on two sides of the casing 21. FIG. 3 is a schematically cross-sectional side view showing the tray 24, which is moved out of the casing 21. As shown in FIG. 3, the casing 21 is composed of an upper casing 35 and the lower casing 22 to form a hollow shape, a main circuit board 36 is disposed at the rear end of the casing 21, and an opening allowing the tray 24 to slide into and out of the casing 21 is formed at the front end of the casing 21. A spindle motor 38 for rotating an optical disk 37, an optical pickup 39 sliding in a radial direction of the optical disk 37 to read data, and a sub-circuit board 40 having electronic elements such as control ICs are disposed on the tray 24. The sub-circuit board 40 on the tray 24 is electrically connected to the main circuit board 36 through a flexible cable 41, which supplies the power, controls signals and transmits data. In addition, the flexible cable 41 still has a wire, which is connected to the bottom plate 25 to form the grounding path through the main circuit board 36, or directly grounds the casing 21.

FIG. 4 is a partially schematically cross-sectional side view showing the optical drive of FIG. 2 taken along the line A-A. As shown in FIG. 4, the front end of the tray 24 is connected to the panel 26 in the electrostatic discharge protection device 23 of the invention. The panel 26 has a hole 42 through which the button 27 passes. The electrostatic discharge protection device 23 is attached to the front end surface of the tray 24 and disposed between the tray 24 and the panel 26. The electrostatic discharge protection device 23 has the push switch 31 at the position corresponding to the button 27. The backside of the tray 24 covers the bottom plate 25. The bent flanges 30 at the front end of the bottom plate 25 lock the front edge of the tray 24 and press the electrostatic discharge protection device 23. The electrostatic discharge protection device 23 has the bare wire 33 near one end of the bottom plate 25. The bare wire 33 may be electrically connected to the bent flange 30 through the bottom plate 25. The bare wire 33 disposed near the button 27, the indicator hole 28 and the emergency ejecting hole 29 on the panel 26 discharges the electrostatic charges passing through the slits to the bottom plate 25. Then, the electrostatic charges are then grounded through the flexible cable 41 and the main circuit board 36 or directly discharged through the casing 21.

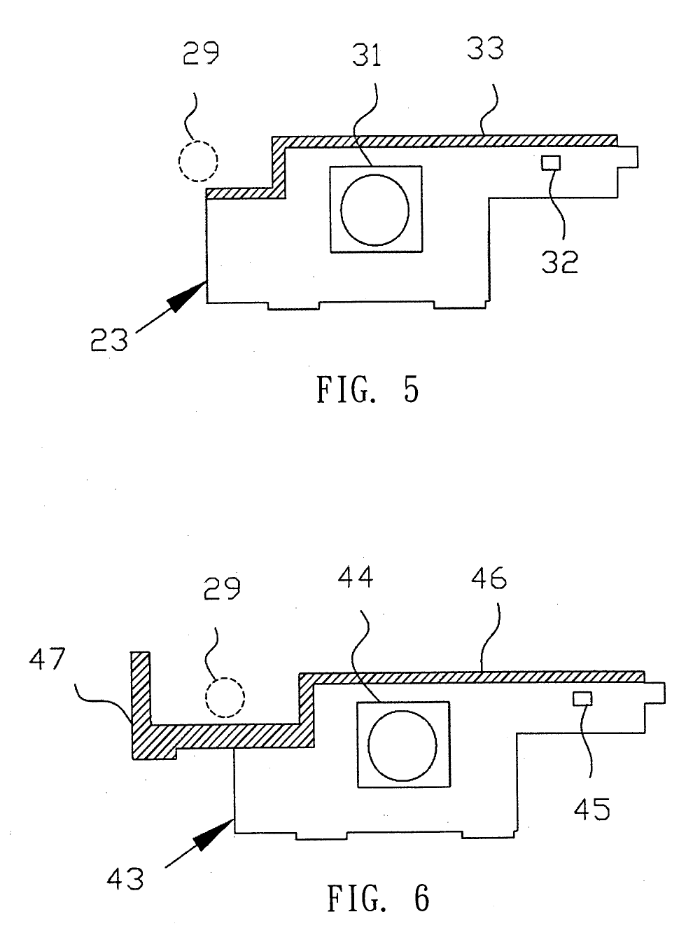

Thus, as shown in FIG. 5, the invention can form the bare wire 33 by the original printed circuit board for the push switch 31 and the light-emitting diode 32 in the suitable redundant space of the optical drive, and the bare wire 33 may be disposed near the slits of the button, the indicator hole and the emergency ejecting hole of the panel so as to constitute the electrostatic discharge protection device 23. Then, the original members, such as the bottom plate, the flexible cable and the main circuit board, may be utilized to form the grounding circuit to discharge the electrostatic charges in the optical drive. Thus, the cost of the eliminated metal sheet can be saved, the structure can be simplified, the number of assembled elements can be reduced, the time for assembling the optical drive can be shortened, and the overall manufacturing cost of the optical drive can be reduced. Meanwhile, the invention may also effectively discharge the electrostatic charges when the tray is moved out of the casing according to the movable connection of the flexible cable. Thus, the electrostatic discharge protection function of the optical drive can be enhanced.

FIG. 6 is a front view showing an electrostatic discharge protection device 43 according to another embodiment of the invention. As shown in FIG. 6, the electrostatic discharge protection device 43 of this embodiment is a printed circuit board for a push switch 44 and a light-emitting diode 45 of the optical drive and has the structure of a bare wire 46. The electrostatic discharge protection device 43 is basically the same as the electrostatic discharge protection device 23 of the previous embodiment except that this embodiment further has an enhanced bare wire 47 disposed outside the original printed circuit board so that the bare wire 46 can surround the emergency ejecting hole 29 with the U-shaped enhanced bare wire 47 to enhance the electrostatic discharge effect. Meanwhile, the enhanced bare wire 47 is more protrudent so as to contact the casing 21 directly to discharge the electrostatic charges when the tray 24 is moved into the optical drive. So, it is unnecessary to discharge the electrostatic charges through the bottom plate 25, and the objects of simplifying the structure and decreasing the element cost still may be achieved.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrostatic discharge protection device of an optical drive being a circuit on a printed circuit board, the electrostatic discharge protection device comprising:
a push switch for enabling a disk-ejecting switch circuit of the optical drive; and
at least one bare wire formed on a grounding bare circuit on the printed circuit board and disposed near the push switch.

2. The protection device according to claim 1, wherein the optical drive comprises a tray and a panel connected to a front end of the tray, and the electrostatic discharge protection device is disposed between the tray and the panel.

3. The protection device according to claim 2, wherein the electrostatic discharge protection device is disposed on a front end surface of the tray.

4. The protection device according to claim 2, wherein the panel has a button at a position corresponding to the push switch.

5. The protection device according to claim 2, further comprising a circuit of a light-emitting diode on the printed circuit board, wherein the bare wire extends near the light-emitting diode.

6. The protection device according to claim 5, wherein the panel is formed with an indicator hole at a position corresponding to the light-emitting diode.

7. The protection device according to claim 2, wherein the panel is formed with an emergency ejecting hole, and the bare wire extends near the emergency ejecting hole.

8. The protection device according to claim 7, wherein the bare wire surrounds the emergency ejecting hole with an enhanced bare wire.

9. The protection device according to claim 2, wherein a bottom plate made of a metallic material covers a backside of the tray and contacts the bare wire.

10. The protection device according to claim 9, wherein at least one bent flange in contact with the bare wire is disposed on a front end of the bottom plate.

11. The protection device according to claim 9, wherein the optical drive further comprises a casing and a main circuit board disposed in the casing, and the bottom plate is connected to the main circuit board through a flexible cable to form a grounding path.

12. The protection device according to claim 11, wherein the bottom plate is connected to the casing to form the grounding path through the flexible cable.

13. The protection device according to claim 2, wherein the optical drive further comprises a casing, the tray can be moved into and out of the casing, the bare wire extends to form an enhanced bare wire, and the enhanced bare wire directly contacts the casing to form a grounding path when the tray is moved into the optical drive.
